(19) United States
(12) Patent Application Publication
(10) Pub. No.: US 2003/0127053 A1
(43) Pub. Date: Jul. 10, 2003

(54) Apparatus and method for supplying cesium

(75) Inventor: Daesig Kim, Pleasanton, CA (US)

Correspondence Address: MORGAN LEWIS & BOCKIUS LLP, 1111 PENNSYLVANIA AVENUE NW, WASHINGTON, DC, 20004, US

(73) Assignee: Filteray Fiber Optics, Inc.

(21) Appl. No.: 10/084,335

(22) Filed: Feb. 28, 2002

(30) Foreign Application Priority Data
Jan. 4, 2002 (KR) P2002-0000448

(51) Int. Cl. C23C 16/00

(52) U.S. Cl. 118/726

(57) ABSTRACT

An apparatus and method for supplying cesium that can readily control the amount of supplied cesium gas and continuously supply the cesium gas for a long period of time are disclosed in the present invention. The apparatus for supplying cesium includes a gas flow controller controlling an amount of an externally introduced inert gas, a pre-heater pre-heating the inert gas introduced through a first gas flow tube from the gas flow controller, a cesium vaporizer emitting a cesium gas from a cesium containing source to a third gas flow tube by using the inert gas introduced through a second gas flow tube from the pre-heater, and a pressure detector detecting a vapor pressure of the cesium vaporizer. It is emphasized that this abstract is provided to comply with the rules requiring an abstract that will allow a searcher or other reader to quickly ascertain the subject matter of the technical disclosure. It is submitted with the understanding that it will not be used to interpret or limit the scope or meaning of the claims.

This application claims the benefit of Korean Application No. P2002-0000448 filed on Jan. 04, 2002, which is hereby incorporated by reference.

### BACKGROUND OF THE INVENTION

1. Field of the Invention

The present invention relates to an apparatus and method for supplying gas in a thin film deposition system, and more particularly, to an apparatus and method for supplying cesium (Cs). Although the present invention is suitable for a wide scope of applications, it is particularly suitable for readily controlling the amount of supplied cesium gas and continuously supplying cesium for a long period of time.

2. Discussion of the Related Art

Generally, an ion source is used in ion injection, sputter deposition, ion beam deposition, and ion spectroscopy. More specifically, when sufficient amount of cesium ions exists on the surface of the substrate to be processed, the cesium ions decrease the work function of the surface of the substrate. This is because cesium has a low electron affinity. Therefore, the cesium existing on the surface of the substrate increases an amount of the negative ion emission.

Under the atmospheric pressure, cesium has a liquid point of 28° C. and a boiling point of 690° C. At 150° C., cesium has a vapor pressure of 7 mTorr.

However, cesium is easily oxidized when it is exposed to oxygen. Moreover, cesium explodes when it is brought into contact with humidity. Therefore, vapor pressure of cesium cannot be controlled easily, which results in many limitations in the application of cesium.

A related art apparatus for supplying cesium will be described with reference to the accompanying drawings.

FIG. 1 illustrates a schematic view of the related art apparatus for supplying cesium using solid electrolyte, which is disclosed in U.S. Pat. No. 5,521,389.

As shown in FIG. 1, the related art apparatus for supplying cesium using solid electrolyte includes an ion pellet 11 having a cesium compound in the form of an oxide sealed therein, an ion emitter 12 emitting cesium ions from the cesium compound inside the ion pellet 11 when brought into contact with metal, and a heater 13 heating the ion pellet 11 so that cesium ions can be emitted through the ion emitter 12.

The related art apparatus for supplying cesium also includes a heat cutoff layer (not shown), which is made of molybdenum and tantalum and formed on an outer surface of the heater 13 in order to prevent heat produced from the heater 13 to be radiated to outside. An anode electrode (not shown) for an electrical connection of the ion pellet 11 and a metal tube (not shown) preventing the cesium compound from flowing out of the ion pellet 11 are also included in the apparatus.

Herein, the ion emitter 12 is a porous electrode coated with tungsten on a side surface of the ion pellet 11. Also, the heater 13 formed on the circumference of the ion pellet is made of a filament coated with alumina.

As described above, in the related art apparatus for supplying cesium using solid electrolyte, the solid electrolyte including cesium emits cesium ions at an elevated temperature ranging from 900 to 1000° C. For an effective emission of the electrodes, the temperature should be maintained at least at 1000° C.

Due to a limited amount of solid electrolyte sealed within the ion pellet 11, this type of cesium source is not desirable for a long-term use. Particularly, ion beam flux is limited. Therefore, it is difficult to carry out a deposition process on a wide surface.

In addition, when the ion pellet 11 is used under an oxygen environment for a long period of time, an oxide layer is formed on the porous ion emitter 12 due to oxidation of cesium, which results in an instability in the discharged amount of cesium ions. Therefore, in order to accurately control the discharged amount of cesium ions, an apparatus that can control the heating of the ion pellet 11 by measuring the discharged amount is required.

FIG. 2 illustrates a schematic view of an apparatus for supplying cesium using a refractory metal ribbon, which is disclosed in U.S. Pat. No. 5,466,941. This structure resolves the problems caused in the apparatus for supplying cesium using solid electrolyte.

As shown in FIG. 2, the apparatus for supplying cesium using a refractory metal ribbon includes an extraction electrode pair 21, a refractory metal ribbon 22 ionizing the cesium discharged from the extraction electrode 21, and an electrode for forming a beam (not shown) formed on the upper and lower portions of the refractory metal ribbon 22 in order to form the positively charged ionized cesium ions into a beam.

A heater (not shown) controlling vapor pressure used for discharging non-ionized cesium to the refractory metal ribbon 22 is also included in the apparatus. Herein, the refractory metal ribbon is formed of tungsten.

However, in the apparatus for supplying cesium using a refractory metal ribbon with the above structure, the extraction electrode 21 must be heated at an elevated temperature ranging from 300 to 400° C. in order to discharge non-ionized cesium. Furthermore, the refractory metal ribbon 22 must be heated at an elevated temperature of 1200° C. in order to positively charge the discharged cesium.

### SUMMARY OF THE INVENTION

Accordingly, the present invention is directed to an apparatus and method for supplying cesium that substantially obviates one or more of problems due to limitations and disadvantages of the related art.

Another object of the present invention is to provide an apparatus and method for supplying cesium that can accurately regulate the amount of cesium gas by using bubbles generated by an inert gas to supply cesium gas and an accurate control of the temperature and pressure of the apparatus to control the partial pressure of cesium.

Additional features and advantages of the invention will be set forth in the description which follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, an apparatus for supplying cesium according to the present invention includes a gas flow controller controlling an amount of an externally introduced inert gas, a pre-heater pre-heating the inert gas introduced through a first gas flow tube from the gas flow controller, a cesium vaporizer emitting a cesium gas from a cesium containing source to a third gas flow tube by using the inert gas introduced through a second gas flow tube from the pre-heater, and a pressure detector detecting a vapor pressure of the cesium vaporizer.

A method for supplying cesium includes controlling an amount of an externally introduced inert gas, pre-heating the inert gas, emitting a cesium gas by using the pre-heated inert gas and a bubbler, and controlling the emitted amounts of cesium gas and inert gas to supply.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention.

In the drawings:

FIG. 1 illustrates a schematic view of a related art apparatus for supplying cesium using solid electrolyte;

FIG. 2 illustrates a schematic view of a related art apparatus for supplying cesium using a refractory metal ribbon; and

FIG. 3 illustrates a schematic view of an apparatus for supplying cesium according to the present invention.

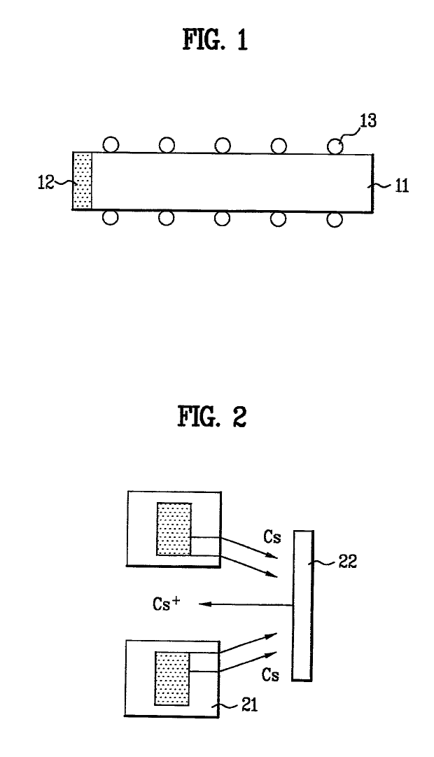

### DETAILED DESCRIPTION OF THE ILLUSTRATED EMBODIMENTS

Reference will now be made in detail to the illustrated embodiments of the present invention, examples of which are illustrated in the accompanying drawings. Wherever possible, the same reference numbers will be used throughout the drawings to refer to the same or like parts.

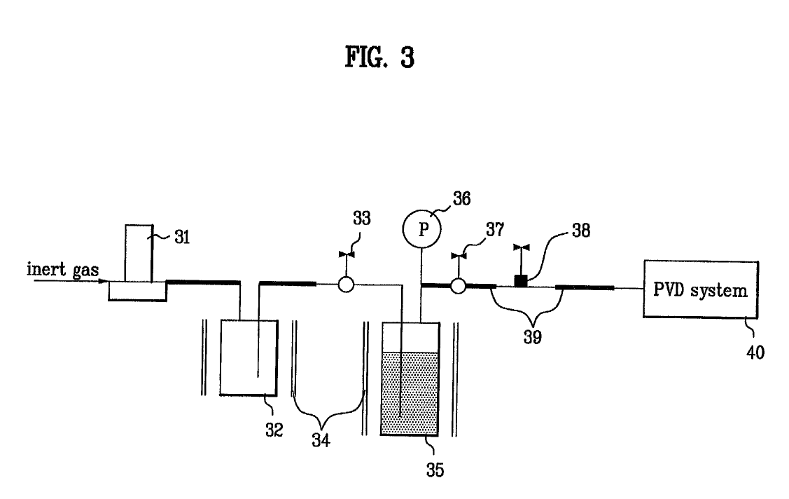

FIG. 3 illustrates a schematic view of an apparatus for supplying cesium according to the present invention.

As shown in FIG. 3, the apparatus for supplying cesium according to the present invention includes a gas flow controller 31 controlling the amount of externally introduced inert gas, a pre-heater 32 pre-heating the inert gas introduced through a first gas flow tube from the gas flow controller 31, a cesium vaporizer 35 emitting cesium gas to a third gas flow tube by using the inert gas introduced through a second gas flow tube from the pre-heater 32 and a bubbler, a pressure detector 36 detecting vapor pressure of the cesium vaporizer 35, a pressure control valve 38 controlling vapor pressure of the cesium vaporizer 35 by opening and closing the third gas flow tube, a gas introduction tube introducing cesium gas, which is transited through the pressure control valve 38, to a vapor deposition system such as a physical vapor deposition system, a first cutoff valve 33 supplying and cutting off the inert gas supplied to the cesium vaporizer 35 to the pre-heater 32, and a second cutoff valve 37 supplying and cutting off the cesium gas emitted to the third gas flow tube from the cesium vaporizer 35.

The apparatus for supplying cesium according to the present invention also includes a heater 34 heating the pre-heater 32 and the cesium vaporizer 35, and heating wires 39 heating the first, second, and third gas flow tubes.

The apparatus for supplying cesium is not only applicable to the PVD system, but also to any vapor deposition system using ion beam, a chemical mechanical vapor deposition system, a display device of an electronic tube or a camera tube, an electronic microscope, and a photoelectron generator.

In addition to argon (Ar) gas, nitrogen (N₂) gas and helium (He) gas may be used as an inert gas. Also, the cesium vaporizer 35 may be filled with one of liquid and solid cesium, and a cesium compound formed of liquid cesium and solid cesium.

When the cesium vaporizer 35 is filled with liquid cesium, the second gas flow tube is inserted into the liquid cesium in the cesium vaporizer 35. Herein, the argon gas produces bubbles.

In other words, when the liquid cesium is used as filling, one side of the second gas flow tube may be positioned inside the liquid cesium and the other side of the third gas flow tube may be positioned higher than the surface of the liquid cesium.

Conversely, when solid cesium or a cesium compound, which is formed by mixing cesium modernite and liquid cesium, is used as filling, the second gas flow tube and the third gas flow tube may be installed in an order opposite to that of the liquid cesium.

The operation of the apparatus for supplying cesium of the present invention having the above structure will now be described.

A heater 34 installed on the circumferential surface of the pre-heater 32 pre-heats the gas introduced to the pre-heater 32 from the gas flow controller 21. The pre-heated gas is introduced with the cesium vaporizer 35 through the second gas flow tube. Due to the gas, the liquid cesium filled within the cesium vaporizer 35 produces bubbles.

Herein, the cesium vaporizer 35 is heated by the heater 34 at the temperature ranging from about 80 to 250° C. and vaporizes the cesium. The heating wire 39 maintains the first, second, and third gas flow tubes at about the same temperature. The entire cesium supplying apparatus except for the gas flow controller 31 and the third gas flow tube may be inserted within a heating oven in order to uniformly control the temperature.

An optimum heating temperature for obtaining a desired amount of cesium gas may vary between the range of 40 to 300° C. depending on the processing pressure. In the present invention, the processing pressure is the pressure at a plasma forming region, which is between the order of mTorr and Torr, thereby being heated at the temperature ranging from about 80 to 250° C. In addition, the pressure detector 36 and the pressure control valve 38 are sequentially controlled. Thus, the amount of cesium gas to be supplied into the chamber may be adequately controlled according to the change in the processing pressure and the pressure of the entire system.

Therefore, the amount of thermodynamically vaporized cesium is determined by stabilizing the temperature and pressure of the cesium vaporizer 35. By bubbling the argon gas, the amount of cesium gas may be supplied and controlled more accurately.

More specifically, the insertion tube is maintained at the temperature higher than that of the entire system excluding the gas flow controller 31. Thus, solid cesium is not clogged in the insertion tube due to cesium oxidation. The problem of clogging due to cesium oxidation, which occurs in the related art, may also be prevented. Therefore, by supplying high quality cesium to the vacuum system, for example a PVD system, negatively charged ions may be easily produced on the substrate to be processed.

In addition, the PVD system may be used in depositing a thin film by using magnetron, which includes DC, pulse DC, or RF power, etc.

The pressure detector 36 measures the vapor pressure of the cesium vaporizer 35. The pressure control valve 38 is controlled in accordance with the measured value. Then, the vapor pressure of the cesium vaporizer 35 is controlled.

Herein, the emitted amount of cesium gas depends on the amounts of argon bubbles and the cesium vaporization. The spread of cesium gas over a substrate also depends on the flux of argon gas. Moreover, by blowing an inert gas, a counter flow of oxygen or other oxidizing substances from the deposition system may be prevented. Thus, cesium vapor may be obtained for a long-term period without any deterioration.

Therefore, by controlling the gas flow controller 31 the amount of argon gas is accurately regulated. Also, the amount of cesium vaporization is regulated by controlling the pressure control valve 38 and the heater 34.

Table 1 compares the results of experimental values of a sputter system using the related art apparatus for supplying cesium and the apparatus for supplying cesium of the present invention.

TABLE 1

| | Related art | Present invention |
|---|---|---|
| Initial system | 2E−6 Torr | 0.9E−4 Torr |
| pressure | | |
| Pressure with | 4.7E−5 Torr | 1.4E−3 Torr |
| supplied cesium | (Heating | (Heating |
| | temerature 180° C.) | temperature 100° C.) |
| Pressure with | 1.3E−3 Torr | 1.4E−3 Torr |
| supplied argon | (Amount of argon | (Amount of argon |
| | 25 sccm) | 5 sccm) |
| Amount of vapor | 0.9 sccm | 0.83 sccm |

In a general sputter system, about 1 sccm of cesium vapor must be supplied to the system in order to obtain the negatively charged ion sputter effect caused by cesium.

As shown in Table 1, when the pellet of the related art apparatus for supplying cesium is heated at a temperature of about 180° C. to form cesium vapor, the pressure of the sputter system elevates from 2E-6 Torr to 4.7E-5 Torr. The value of the elevated system pressure converted into the amount of cesium vapor is 0.9 sccm.

Meanwhile, when the cesium vaporizer 35 of the apparatus for supplying cesium of the present invention is heated to a temperature of about 100° C. to form cesium vapor, the pressure of the sputter system elevated from about 0.9E-4 Torr to about 3E-4 Torr. When argon gas is introduced, the pressure increases to about 1.4E-3 Torr.

The amount of cesium vapor produced by the apparatus for supplying cesium of the present invention is about 0.83 sccm.

In other words, when vaporizing cesium by using the apparatus for supplying cesium of the present invention, almost the same amount of stable cesium gas is supplied for a long period of time at a temperature lower than that of the related art apparatus for supplying cesium.

The above-described apparatus for supplying cesium according to the present invention has the following advantages.

A heater or heating wires are installed, so that the temperature of the entire system including a pre-heater, a cesium vaporizer, and gas flow tubes is readily maintained and controlled. In addition, by using a pressure control valve to accurately control the pressure of the cesium vaporizer, the vaporized amount of cesium gas is regulated with reliability.

By using an inert gas, such as argon, helium, nitrogen, etc., as a carrier to supply cesium gas, the supplied amount of cesium gas is regulated with precision. Also, a counter flow of oxygen or other oxidizing substances into a cesium introducing tube is avoided, thereby preventing cesium oxidation.

Additionally, by using liquid cesium under an inert environment in a vacuum condition, cesium gas can be stably supplied for a long period of time without being deteriorated.

The flux of cesium is controlled in accordance with the amount of argon gas, thereby enabling thin film deposition on a large area.

The temperature of the cesium introducing tube is independently controlled to be higher than that of the cesium vaporizer. Therefore, clogging of the cesium introducing tube is prevented, which facilitates maintenance of the apparatus.

It will be apparent to those skilled in the art that various modifications and variations can be made in the apparatus and method for supplying cesium of the present invention without departing from the spirit or scope of the inventions. Thus, it is intended that the present invention covers the modifications and variations of this invention provided they come within the scope of the appended claims and their equivalents.

What is claimed is:

1. An apparatus for supplying cesium, comprising:
a gas flow controller controlling an amount of an externally introduced inert gas;
a pre-heater pre-heating the inert gas introduced through a first gas flow tube from the gas flow controller;
a cesium vaporizer emitting a cesium gas from a cesium containing source to a third gas flow tube by using the inert gas introduced through a second gas flow tube from the pre-heater; and
a pressure detector detecting a vapor pressure of the cesium vaporizer.

2. The apparatus according to claim 1, wherein the inert gas includes one of argon gas, nitrogen gas, and helium gas.

3. The apparatus according to claim 1, wherein the cesium containing source includes one of liquid cesium, solid cesium, and a cesium compound formed of a mixture of the liquid cesium and the solid cesium.

4. The apparatus according to claim 1, wherein the cesium vaporizer emits the cesium gas through a plurality of bubbles formed by the inert gas.

5. The apparatus according to claim 1, further comprising:
a heater heating the pre-heater and the cesium vaporizer; and
a plurality of heating wires heating the first, second, and third gas flow tubes.

6. The apparatus according to claim 1, wherein further comprising a cutoff valve on each of the second and third gas flow tubes.

7. The apparatus according to claim 1, wherein the pressure control valve controls the vapor pressure of the cesium vaporizer by opening and closing the third gas flow tube.

8. The apparatus according to claim 1, wherein the apparatus for supplying cesium is used in chemical vapor deposition, physical vapor deposition, vapor deposition using ion beam, display device tube or camera tube, electronic microscope, and photoelectron generator.

9. The apparatus according to claim 1, wherein the cesium vaporizer is heated at a temperature ranging from about 80 to 250° C. when a process pressure is within a plasma forming range of an order of mTorr to Torr.

10. The apparatus according to claim 1, wherein the pre-heater and the cesium vaporizer are both introduced into an oven to be heated at a temperature ranging from about 80 to 250° C. when a process pressure within a plasma forming range of an order of mTorr to Torr.

11. The apparatus according to claim 1, further comprising:
a gas introduction tube introducing the cesium gas passed through the pressure control valve.

12. The apparatus according to claim 11, wherein the gas introduction tube is heated at a temperature higher than that of the cesium vaporizer.

13. A method for supplying cesium, comprising:
controlling an amount of an externally introduced inert gas;
pre-heating the inert gas;
emitting a cesium gas by using the pre-heated inert gas and a bubbler; and
controlling the emitted amounts of cesium gas and inert gas to supply.

14. The method according to claim 13, wherein the controlled emitted amounts of cesium gas and inert gas are heated at a temperature higher than the emitted cesium gas by using the pre-heated inert gas and a bubbler.
